(19) United States
(12) Patent Application Publication
(10) Pub. No.: US 2025/0253138 A1
(43) Pub. Date: Aug. 7, 2025

(54) Plasma Processing Apparatus and Plasma Processing Method

(71) Applicant: Tokyo Electron Limited, Tokyo (JP)

(72) Inventors: Eiki KAMATA, Yamanashi (JP); Hiroyuki ONODA, Tokyo (JP); Taro IKEDA, Yamanashi (JP)

(21) Appl. No.: 19/190,422

(22) Filed: Apr. 25, 2025

Related U.S. Application Data
(63) Continuation of application No. PCT/JP2023/039297, filed on Oct. 31, 2023.

(30) Foreign Application Priority Data
Nov. 11, 2022 (JP) 2022-181314

(51) Int. Cl. H01J 37/32; H01L 21/02

(52) U.S. Cl. CPC H01J 37/32449; H01L 21/02087; H01J 2237/24578; H01J 2237/334

(57) ABSTRACT

A plasma processing apparatus for removing a film formed on a peripheral portion of a substrate by using plasma comprises a processing chamber configured to be depressurized and accommodate a substrate, a substrate support provided in the processing chamber and having an upper surface serving as a placing table on which a substrate is placed, a discharge head provided above the substrate support and configured to discharge a gas toward the placing surface, and a plasma supply mechanism configured to supply plasma to an edge of the substrate placed on the placing surface. The plasma processing apparatus further comprises an adjustment mechanism configured to adjust a relative position and inclination of the discharge head and the substrate support.

### CROSS-REFERENCE TO RELATED APPLICATIONS

This application is a bypass continuation application of International Application No. PCT/J P 2023/039297 having an international filing date of Oct. 31, 2023 and designating the United States, the International Application being based upon and claiming the benefit of priority from Japanese Patent Application No. 2022-181314 filed on Nov. 11, 2022, the entire contents of which are incorporated herein by reference.

### TECHNICAL FIELD

The present disclosure relates to a plasma processing apparatus and a plasma processing method.

### BACKGROUND

Japanese Laid-open Patent Publication No. 2021-197244 discloses a plasma processing apparatus for performing plasma processing on an edge of a substrate. The plasma processing apparatus includes a processing chamber, a substrate support member that supports the substrate except at least the edge thereof to be subjected to plasma processing in the processing chamber, and to which a high-frequency power is applied, and having at least a side surface made of a dielectric material, and an opposing dielectric member made of a dielectric material and provided to face the substrate support member. Further, the plasma processing apparatus includes a side ground electrode having a ground potential and provided at a position that is close to the substrate supported by the substrate support member on the lateral side of the substrate so that electrical coupling occurs between itself and the edge surface of the substrate. In the plasma processing apparatus, an etching gas is supplied to the edge of the substrate. Further, a gas channel is provided at the central portion of the opposing dielectric member, and an inert gas is supplied to the central portion of the substrate through the gas flow path. Accordingly, the flow of the inert gas from the central portion toward the edge of the substrate is generated, thereby preventing the etching gas from reaching the central portion of the substrate.

### SUMMARY

The technique of the present disclosure performs bevel cleaning for removing a film formed on a periphery of a substrate using plasma uniformly and effectively in a circumferential direction of the substrate.

According to one embodiment of present disclosure, a plasma processing apparatus for removing a film formed on a peripheral portion of a substrate by using plasma is provided. The plasma processing apparatus comprises a processing chamber configured to be depressurized and accommodate a substrate, a substrate support provided in the processing chamber and having an upper surface serving as a placing table on which a substrate is placed, a discharge head provided above the substrate support and configured to discharge a gas toward the placing surface, a plasma supply mechanism configured to supply plasma to an edge of the substrate placed on the placing surface, and an adjustment mechanism configured to adjust a relative position and inclination of the discharge head and the substrate support.

### BRIEF DESCRIPTION OF THE DRAWINGS

FIG. 1 is a vertical cross-sectional view showing an outline of a configuration of a plasma processing apparatus according to an embodiment.

FIG. 2 is a diagram showing an example of the arrangement of a camera as a detection part and a camera as another detection part.

FIG. 3 is a graph showing a simulation result obtained in the case of changing the flow rate of Ar gas as an inert gas discharged from a discharge hole of a discharge head.

FIG. 4 is a graph showing the relationship between a size of a gap between a periphery of a bottom surface of the discharge head and a surface of a periphery of a wafer placed on a placing surface, in which a ratio of O₂ radicals is 1% at positions where the distances from the peripheral edge of the discharge head are 5 mm and 3 mm, and the flow rate of Ar gas discharged from the discharge head.

FIG. 5 is a graph showing the relationship between inclination of a linear approximation formula indicating the relationship in FIG. 4 and the distance from the peripheral edge of the discharge head at which the ratio of O₂ radicals is 1%.

FIG. 6 is a diagram showing another example of a discharge head.

### DETAILED DESCRIPTION

In a manufacturing process of semiconductor devices, various processes such as film formation and the like are performed on a substrate such as a semiconductor wafer (hereinafter, referred to as “wafer”).

After the film formation, an unnecessary film may be formed on the periphery of the substrate, including a bevel portion thereof. The unnecessary film formed on the bevel portion has low adhesion to the substrate, and may be peeled off during transfer of the substrate and contaminate another substrate or the inside of the device.

In order to prevent the contamination, bevel cleaning may be performed to remove an unnecessary film formed on the periphery of the substrate.

The technique disclosed in Patent Document 1, which uses plasma, is an example of the technique related to the bevel cleaning.

A plasma processing apparatus that performs bevel cleaning using plasma includes, for example, a substrate support table having a placing surface on which a substrate is placed, a discharge head that is provided above the substrate support table and discharges a gas toward the placing surface, and a plasma supply mechanism that supplies plasma to the edge of the substrate placed on the placing surface. The discharge head discharges a gas from the central portion thereof toward the central portion of the substrate on the placing surface to form gas flow directed from the central portion toward the edge of the substrate between the discharge head and the substrate, thereby preventing the plasma from moving toward the central portion of the substrate.

Further, in order to perform the bevel cleaning uniformly and effectively in the circumferential direction of the substrate, it is preferable that at least the size of the gap between the surface of the peripheral portion of the substrate placed on the placing surface and the bottom surface of the peripheral portion of the discharge head is maintained at a desired value in the entire circumferential direction of the substrate. However, in a conventional plasma processing apparatus that performs the bevel cleaning, even if the apparatus is designed and manufactured such that the size of the gap is maintained at the same level as described above, the size of the gap may not be maintained at a desired value in the entire circumferential direction of the substrate due to the influence of the manufacturing errors of the device or the warpage of the substrate that changes depending on the state (e.g., film thickness or the like) of the film on the substrate.

Therefore, the technique of the present disclosure performs bevel cleaning uniformly and effectively in the circumferential direction of the substrate.

Hereinafter, a plasma processing apparatus and a plasma processing method according to the present embodiment will be described with reference to the accompanying drawings. Further, in this specification, like reference numerals will be used for like parts having substantially the same functional configurations, and redundant description thereof will be omitted.

### <Plasma Processing Apparatus>

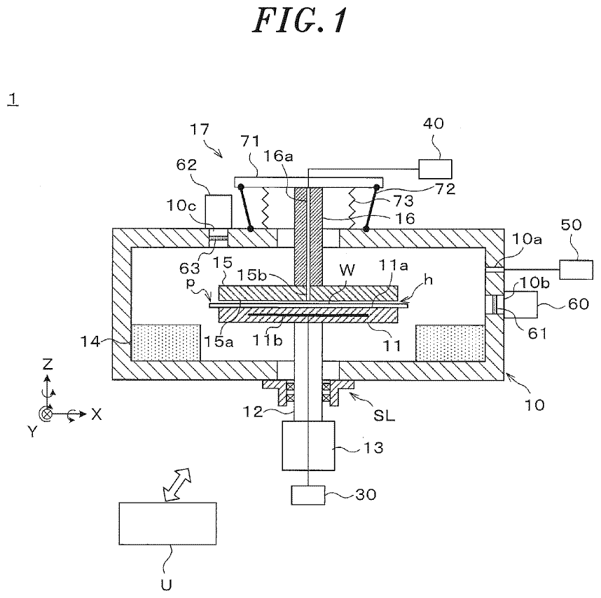

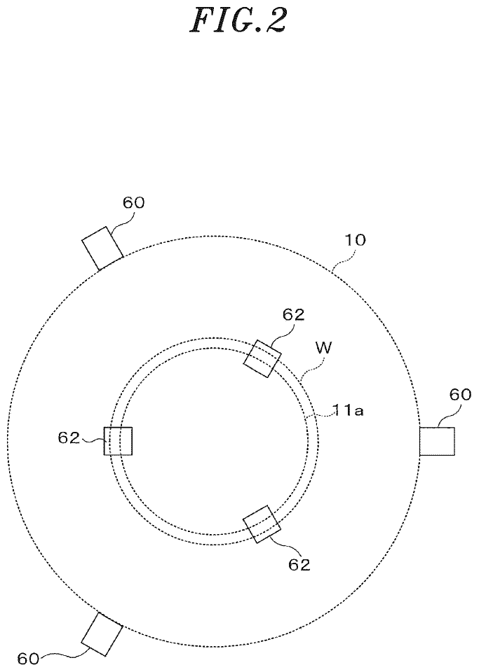

FIG. 1 is a vertical cross-sectional view showing an outline of a configuration of the plasma processing apparatus according to the present embodiment. FIG. 2 is a diagram showing an example of the arrangement of a camera 60 and a camera 62 to be described later.

In the plasma processing apparatus 1, plasma is used to remove a film formed on the peripheral portion of a wafer W as a substrate. The plasma processing apparatus 1 includes a processing chamber 10. The processing chamber 10 can be depressurized, and accommodates the wafer W. Further, the processing chamber 10 is formed in a cylindrical shape, for example, and made of aluminum. The processing chamber 10 is grounded. A loading/unloading port (not shown) for the wafer W is provided on the sidewall of the processing chamber 10, and a gate valve (not shown) for opening and closing the loading/unloading port is provided at the loading/unloading port.

In the processing chamber 10, a stage 11 is provided as a substrate support. The stage 11 supports the wafer W, and the upper surface thereof constitutes a placing surface 11a on which the wafer W is placed. The stage 11 is smaller than the wafer W, and supports the central portion of the backside of the wafer W. Therefore, when the wafer W is supported on the stage 11, the peripheral portion of the wafer W protrudes from the stage 11. The shape of the stage 11 is, for example, a disc shape with a diameter smaller than that of the wafer W. In this specification, “peripheral portion of the wafer W” indicates the peripheral portion of the wafer W that includes at least the bevel portion.

In addition, the stage 11 is provided with an electrode 11b. The electrode 11b is connected to a DC power supply 30. By applying a DC voltage from the DC power supply 30 to the electrode 11b, a Coulomb force is generated, for example, and the wafer W can be electrostatically attracted to the stage 11 by the Coulomb force.

The upper end of a support shaft member 12 is connected to the central portion of the bottom surface of the stage 11. The support shaft member 12 extends in the vertical direction to penetrate the bottom wall of the processing chamber 10. The lower end of the support shaft member 12 is connected to a rotation mechanism 13. The rotation mechanism 13 has, for example, a motor (not shown) as a driving source that generates a driving force for rotating the support shaft member 12 around the axis of the support shaft member 12. As the support shaft member 12 rotates around the axis by the driving of the rotation mechanism 13, the stage 11 and the wafer W placed on the stage 11 rotate around the axis. Further, the rotation mechanism 13 has a slip ring (not shown) for achieving electrical connection between the stage 11 and the DC power supply 30.

A sealing member SL is provided between the support shaft member 12 and the bottom wall of the processing chamber 10. The sealing member SL is a member that seals the space between the bottom wall of the processing chamber and the support shaft member 12 so that the support member 12 can rotate. The sealing member SL is, for example, a magnetic fluid seal.

In addition, an insulating member 14 and a discharge head 15 are provided in the processing chamber 10.

The insulating member 14 is made of an insulating material such as alumina or aluminum nitride. The insulating member 14 is located outside and below the wafer W placed on the placing surface 11a at a position lower than the placing surface 11a of the stage 11. The insulating member 14 is formed, for example, in a circular ring shape when viewed from the top.

The discharge head 15 is made of an insulating material such as alumina, aluminum nitride, or quartz, and is provided above the stage 11, specifically, above the stage 11 such that the placing surface 11a of the stage 11 and the bottom surface 15a of the discharge head 15 face each other. In one embodiment, the discharge head 15 is smaller than the wafer W, and specifically, the bottom surface 15a thereof is formed in a circular shape smaller than that of the wafer W. Therefore, in one embodiment, when the wafer W is supported on the stage 11, the peripheral portion of the wafer W protrudes outward from the peripheral end of the discharge head 15 when viewed from the top.

Further, the discharge head 15 discharges a gas toward the placing surface 11a. Specifically, the discharge head 15 discharges an inert gas, such as argon (Ar) gas, toward the central portion of the wafer W placed on the placing surface 11a through a discharge hole 15b that is opened at the central portion of the bottom surface 15a. The discharge hole 15b is connected to an inert gas supply source 40.

The lower end of the support shaft member 16 is connected to the central portion of the upper surface of the discharge head 15. The support shaft member 16 extends in the vertical direction to penetrate through the ceiling wall of the processing chamber 10. The upper end of the support shaft member 16 is connected to an adjustment mechanism 17. The adjustment mechanism 17 adjusts the position and inclination of the discharge head 15 with respect to the stage 11. The configuration of the adjustment mechanism 17 will be described later.

A gas flow path 16a connected to the discharge hole 15b of the discharge head 15 is provided in the support shaft member 16. The discharge hole 15b is connected to the inert gas supply source 40 through the gas flow path 16a.

Further, an exhaust mechanism (not shown) that exhausts the inside of the processing chamber 10 is connected to the processing chamber 10. The exhaust mechanism is connected to, for example, the bottom wall of the processing chamber 10.

Further, a supply hole 10a is formed in the processing chamber 10. In one embodiment, the supply hole 10a constitutes at least a part of a plasma supply mechanism that supplies plasma to the edge of the wafer W placed on the placing surface 11a. Further, the supply hole 10a is formed, for example, in the sidewall of the processing chamber 10. A remote plasma supply source 50 is connected to the supply hole 10a in order to enable the supply of reactive plasma (specifically, the supply of radicals such as oxygen (O₂) radicals) into the processing chamber through the supply hole 10a. The remote plasma supply source 50 can activate an inert gas such as Ar gas and an oxygen-containing gas such as O₂ gas supplied to the remote plasma supply source 50 with plasma to form O₂ radicals.

Further, the plasma processing apparatus 1 includes the camera 60 as a detection part for detecting the gap between the peripheral portion of the bottom surface 15a of the discharge head 15 and the surface (front surface) of the wafer W placed on the placing surface 11a. Specifically, the camera 60 detects the gap between the periphery of the bottom surface 15a of the discharge head 15 and the surface (front surface), i.e., the upper surface, of the wafer W placed on the placing surface 11a.

The camera 60 is disposed, for example, outside the processing chamber 10. In this case, the camera 60 images a gap h through an optical window 61 provided in the opening 10b of the sidewall of the processing chamber 10. The imaging result is outputted to a controller U to be described later.

The camera 60 is disposed to be able to detect the gap h in at least three locations along the circumferential direction of the placing surface 11a. Specifically, as shown in FIG. 2, a plurality of cameras 60 (three in the illustrated example) are provided along the circumferential direction of the placing surface 11a.

Further, as shown in FIG. 1, the plasma processing apparatus 1 includes the camera 62 as another detection part for detecting the positional relationship between the peripheral edge of the discharge head 15 and the peripheral edge of the wafer W placed on the placing surface 11a. Specifically, the camera 62 detects the peripheral edge of the wafer W (hereinafter, the protruding portion p of the wafer W) placed on the placing surface 11a, which protrudes outward from the peripheral edge of the discharge head 15 when viewed from the top. The camera 62 is disposed, for example, outside the processing chamber 10. In this case, the camera 62 images the protruding portion p of the wafer W through, for example, an optical window 63 provided in an opening 10c of the ceiling wall of the processing chamber 10. The image capture result is outputted to the controller U to be described later.

The camera 62 is provided to be able to detect the protrusion p in at least three locations along the circumferential direction of the placing surface 11a. Specifically, as shown in FIG. 2, a plurality of cameras 62 (three in the illustrated example) are provided along the circumferential direction of the placing surface 11a.

The optical windows 61 and 63 may be made of, for example, quartz glass. The plasma processing apparatus 1 configured as described above includes the controller U. The controller U is a computer including, for example, a processor such as a central processing unit (CPU) and a memory, and includes a program storage part (not shown). The program storage part stores a program including commands for implementing wafer processing to be described later using the plasma processing apparatus 1. Further, the program may be recorded in a computer-readable storage medium, and may be installed from the storage medium into the controller U. Further, the storage medium may a temporary storage medium or a non-temporary storage medium. Further, the program may be partially or entirely implemented by dedicated hardware (circuit board).

### <Adjustment Mechanism 17>

Next, an example of the configuration of the adjustment mechanism 17 will be described.

The adjustment mechanism 17 includes, for example, a base member 71, a plurality of (for example, six) actuators 72, and a bellows 73.

The base member 71 is connected to the upper end of the support shaft member 16 located outside the processing chamber 10. Since the upper end of the support shaft member 16 is connected to the base member 71, the discharge head 15 can move integrally with the base member 71.

The plurality of actuators 72 are provided in parallel between the ceiling wall of the processing chamber 10 and the base member 71, and adjust the position and inclination of the discharge head 15 with respect to the stage 11 by moving the base member 71 relative to the ceiling wall of the processing chamber 10. Each of the actuators 72 is extensible and contractible, and is slidably connected to the base member 71 via a universal joint (not shown). Each of the actuators 72 is rotatably and slidably connected to the ceiling wall of the processing chamber 10 via a spherical joint (not shown). The plurality of actuators 72 and the base member 71 form a parallel link mechanism that can move the base member 71 in, for example, the X-axis direction, the Y-axis direction, the Z-axis direction, the rotation direction around the X-axis, the rotation direction around the Y-axis, and the rotation direction around the Z-axis, as shown in FIG. 1. The movement coordinate system of the parallel link mechanism formed by the plurality of actuators 72 and the base member 71 is adjusted in advance to match the coordinate system of the processing chamber 10. The parallel link mechanism connects the ceiling wall of the processing chamber 10 and the base member 71, so that the plurality of actuators 72 can move the base member 71 relative to the ceiling wall of the processing chamber 10. Accordingly, the position and inclination of the discharge head 15 with respect to the stage 11 can be adjusted. For example, the plurality of actuators 72 move the base member 71 in a direction (for example, the Z-axis direction in FIG. 1) perpendicular to the outer wall surface of the ceiling wall of the processing chamber 10, thereby adjusting the position of the discharge head 15 with respect to the stage 11. Further, for example, the plurality of actuators 72 move the base member 71 in directions (for example, the X-axis direction and the Y-axis direction in FIG. 1) along the outer wall surface of the ceiling wall of the processing chamber 10, thereby adjusting the position of the discharge head 15 with respect to the stage 11. Further, for example, the plurality of actuators 72 tilt the base member 71 in predetermined directions (for example, the rotation direction around the X-axis and the rotation direction around the Y-axis in FIG. 1) with respect to the outer wall surface of the ceiling wall of the processing chamber 10, thereby adjusting the inclination of the discharge head 15 with respect to the stage 11.

Further, the position and inclination of the discharge head 15 with respect to the stage 11, which are adjusted by the plurality of actuators 72, can be specified by detecting the position and inclination of the base member 71 using various detection devices. The detection devices may be, for example, a linear encoder, a gyro sensor, a three-axis acceleration sensor, a laser tracker, and the like.

### Example of Wafer Processing

Next, an example of wafer processing performed using the plasma processing apparatus 1 will be described. Further, the operations in the following steps are performed under the control of the controller U. Further, the wafer W to be processed by the plasma processing apparatus 1 has been subjected to film formation.

### (Step S1: Placing of Wafer W)

For example, first, the wafer W is placed on the placing surface 11a of the stage 11.

Specifically, for example, the wafer W is loaded into the processing chamber 10 in a state where the discharge head 15 is located at a retracted position separated from the stage 11, and the wafer W is placed on the placing surface 11a via lift pins (not shown) provided for the stage 11. Then, a DC voltage is applied from the DC power supply 30 to the electrode 11b of the stage 11, so that the wafer W is electrostatically attracted and held on the stage 11. After the wafer W is loaded, a pressure in the processing chamber 10 is reduced to a predetermined vacuum level by an exhaust mechanism (not shown). Further, the discharge head 15 is lowered by the adjustment mechanism 17, and moved to a processing position close to the stage 11.

### (Step S2: Detection of Gap h)

Then, the gap h between the bottom surface of the peripheral portion of the discharge head 15 and the surface of the wafer W placed on the placing surface 11a is detected.

Specifically, for example, the gap h is imaged by each of the cameras 60, and the imaging results are outputted to the controller U. Then, the controller U calculates a size H of the gap h at the position corresponding to each camera 60 based on the imaging results.

### (Step S3: Adjustment of Position and Inclination of Discharge Head 15)

Then, based on the detection result of the gap h, either the position or the inclination of the discharge head 15 with respect to the stage 11 is adjusted. Specifically, based on the detection result of the gap h, at least one of the position and the inclination of the discharge head 15 with respect to the stage 11 is adjusted such that the size H of the gap h becomes a desired value.

More specifically, for example, based on the calculation result of the size H of the gap h at the position corresponding to each camera 60, the controller U controls the adjustment mechanism 17 to adjust the position and inclination of the discharge head 15 with respect to the stage 11 such that the size H of the gap h at the position corresponding to each camera 60 becomes a target value Ht. Further, when the wafer W is rotated around the vertical axis in the cleaning of subsequent step S4, the controller U may control the adjustment mechanism 17 to adjust the position and inclination of the discharge head 15 with respect to the stage 11 such that a representative value (e.g., average value) of the size H of the gap h at the position corresponding to each camera 60 becomes the target value Ht.

The target value Ht [mm] of the size H of the gap h is set, for example, to satisfy the following formula (A). Further, in Eq. (A), F is the flow rate (unit: slm) of the inert gas discharged from the discharge hole 15b of the discharge head 15 in subsequent step S4. Further, a is the distance (unit: mm, hereinafter, referred to as “allowable distance”) from the peripheral edge of the discharge head 15, which allows radicals to reach the central portion of the wafer through the gap h.

$$H t \leq 0.12 * a * F \qquad ( A )$$

### (Step S4: Cleaning)

Next, the film formed on the peripheral edge of the wafer W is removed by plasma.

Specifically, radicals such as O₂ radicals from the remote plasma supply source 50 are supplied into the processing chamber 10 through the supply hole 10a. The film formed on the peripheral edge of the wafer W is removed by the radicals. In other words, the peripheral edge of the wafer W is cleaned. During cleaning, the stage 11 may be rotated by the rotation mechanism 13, and the wafer W may be rotated around the vertical axis.

Further, simultaneously with the supply of radicals, an inert gas such as Ar gas from the supply source 40 is discharged from the discharge hole 15b of the discharge head 15 toward the wafer W. Accordingly, the flow of the inert gas directed from the central portion toward the peripheral portion of the wafer W is formed between the discharge head 15 and the wafer W (specifically, between the bottom surface 15a of the discharge head 15 and the surface of the wafer W). Hence, radicals are suppressed from reaching the central portion of the wafer W, thereby suppressing the removal of the film at the central portion of the wafer W.

The flow rate F of the inert gas discharged from the discharge hole 15b allows the Peclet number Pe between the discharge head 15 and the placing surface 11a, which is expressed by the following Eq. (B), to be 1 or more.

$$Pe = 6.1859 \times 1 {0}^{- 3} \cdot F / ( 2 π R \cdot {D}_{1} \cdot ( p / T ) ) \qquad ( B )$$

R: radius of the discharge head 15
D₁: interdiffusion coefficient of plasma (i.e. radicals) with respect to the gas discharged from the discharge head 15
p: pressure in the processing chamber 10 (during processing)
T: temperature of the gas discharged from the discharge head 15

By setting the Peclet number Pe to 1 or more, the gas transport is dominated by “flow” rather than “diffusion” and, thus, the radicals can be suppressed from reaching the central portion of the wafer W.

Further, if the flow rate F of the inert gas discharged from the discharge hole 15b is too large, the radicals are less likely to move toward the peripheral portion of the wafer W. Therefore, the flow rate F of the inert gas discharged from the discharge hole 15b is preferably a flow rate at which the Peclet number Pe is 100 or less. Further, in order to suppress the consumption of the inert gas discharged from the discharge hole 15b, it is more preferable that the flow rate F is a flow rate at which the Peclet number is 10 or less.

For example, when a predetermined period of time elapses from the start of the radical supply, the radial supply and the inert gas supply are stopped, and the cleaning of the peripheral portion of the wafer W is completed.

### (Step S5: Unloading of Wafer W)

Then, the wafer W is separated from the stage 11 and unloaded from the processing chamber 10.

Specifically, the wafer W is separated from the stage 11 and unloaded from the processing chamber 10 in the reverse order of step S1.

Accordingly, the series of wafer processing for one wafer W is completed, and the series of wafer processing for a next wafer W is performed.

### Another Example of Wafer Processing

In step S2, in addition to the detection of the gap h, the protrusion p of the wafer W is detected. In step S3, at least one of the position and the inclination of the discharge head 15 with respect to the stage 11 may be adjusted based on the detection results of the gap h and the protrusion p.

In this case, the detection of the protrusion p of the wafer W is specifically performed as follows, for example. In other words, the protrusion p is imaged by each of the plurality of cameras 62, the imaging results are outputted to the controller U. The controller U calculates the protrusion amount P of the protrusion p at the position corresponding to each camera 62 based on the imaging results. Then, in step S3, specifically, based on the detection result of the gap h and the detection result of the protrusion p, at least one of the position and the inclination of the discharge head 15 with respect to the stage 11 is adjusted such that the size H of the gap h and the protrusion amount P of the protrusion p become desired values. More specifically, the controller U controls the adjustment mechanism 17 based on the calculation results of the size H of the gap h at the position corresponding to each camera 60 and the protrusion amount P of the protrusion p at the position corresponding to each camera 62. As a result, the position and the inclination of the discharge head 15 with respect to the stage 11 are adjusted such that the size H of the gap h at the position corresponding to each camera 60 becomes the target value Ht and the protrusion amount P of the protrusion p at the position corresponding to each camera 62 becomes the target value Pt.

Further, after the adjustment of the discharge head 15 with respect to the stage 11 in step S3, the detection of the gap h in step S2 may be performed again. If the size H of the gap h in step S2 is not within a desired range as a result of step S2 that has been executed again, the adjustment in step S3 may be performed again.

### Main Effects of Present Embodiment

As described above, in the present embodiment, the plasma processing apparatus 1 for removing a film formed on the peripheral portion of the wafer W by using plasma includes the processing chamber 10 that is depressurizable and accommodates the wafer W, and the stage 11 provided in the processing chamber and having the upper surface serving as the placing surface 11a on which the wafer W is placed. Further, in the present embodiment, the plasma processing apparatus 1 includes the discharge head 15 provided above the stage 11 and configured to discharge a gas toward the placing surface 11a, and the supply hole 10a constituting the plasma supply mechanism for supplying plasma to the edge of the wafer W placed on the placing surface 11a. Further, in the present embodiment, the plasma processing apparatus 1 includes the adjustment mechanism 17 for adjusting the position and the inclination of the discharge head with respect to the stage 11. Since the adjustment is performed by the adjustment mechanism 17, at least the size H of the gap h between the peripheral portion of the wafer W placed on the placing surface and the bottom surface of the peripheral portion of the discharge head 15 can be substantially uniformly maintained at a desired value in the entire circumferential direction of the wafer, regardless of the type of warpage of the wafer W or the magnitude of the manufacturing errors of the device. Hence, in accordance with the present embodiment, the bevel cleaning for removing the film formed on the peripheral portion of the wafer W by plasma can be performed uniformly and effectively in the circumferential direction of the wafer W, regardless of the type of warpage of the wafer W or the magnitude of the manufacturing errors of the device.

In addition, in the present embodiment, since the plasma processing apparatus 1 includes the adjustment mechanism 17, the positional relationship between the peripheral end of the discharge head 15 and the peripheral end of the wafer W placed on the placing surface 11a can also be appropriately maintained in the entire circumferential direction of the wafer. Specifically, the protrusion amount P of the protrusion p can be substantially uniformly maintained at a desired value in the entire circumferential direction of the wafer W. Therefore, in accordance with the present embodiment, from the above viewpoint, the bevel cleaning can be performed uniformly and effectively in the circumferential direction of the wafer W.

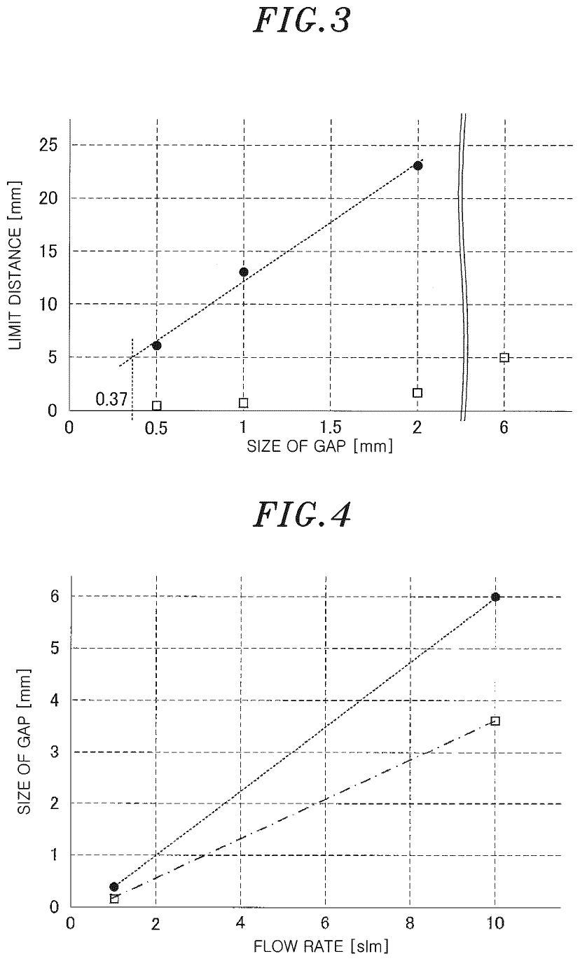

FIG. 3 is a graph showing the result of simulation of the relationship between the size H of the gap h and a distance a′ from the peripheral edge of the discharge head 15 (the distance from the peripheral edge toward the center, hereinafter, referred to as “limit distance”) at which the ratio of O₂ radicals becomes 1% in the case of changing the flow rate of Ar gas as an inert gas discharged from the discharge hole 15b of the discharge head 15. In the graph, a circle (•) indicates the case where the flow rate of Ar gas discharged from the discharge hole 15b is 1 slm, and a square (u) indicates the case where the flow rate of Ar gas discharged from the discharge hole 15b is 10 slm. Further, in the simulation, the protrusion amount of the protrusion p was set to zero. In other words, the discharge head 15 and the wafer W have the same size.

As shown in FIG. 3, in the case where the flow rate of the Ar gas discharged from the discharge hole 15b is 10 slm, the limit distance a′ is 5 mm when the size H of the gap h is 6.0 mm. On the other hand, in the case where the flow rate of the Ar gas discharged from the discharge hole 15b is 1 sim, it is expected that the limit distance a′ is 5 mm when the size H of the gap h is 0.37 mm based on the linear approximation formula of the simulation result. Therefore, when the limit distance a′ is 5 mm, the relationship between the size H of the gap h and the flow rate F of the Ar gas discharged from the discharge hole 15b is expressed by the circle (•) in FIG. 4. Further, when the limit distance a′ is 5 mm, the linear approximation of the result shown in FIG. 4 gives H=0.6015*F.

According to the same simulation results, when the limit distance a′ is 3 mm, the relationship between the size H of the gap h and the flow rate F of the Ar gas discharged from the discharge hole 15b is expressed by the square (□) in FIG. 4. Further, when the limit distance a′ is 3 mm, the linear approximation of the result shown in FIG. 4 gives H=0.3585*F.

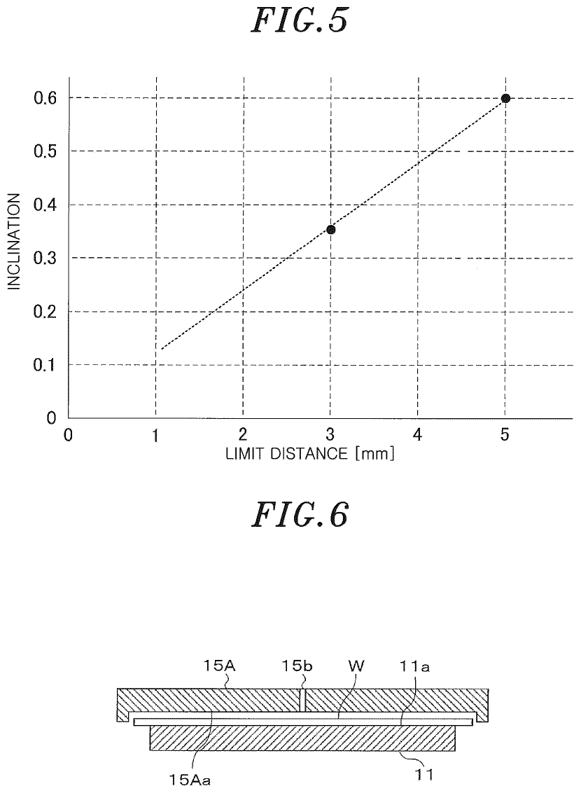

Further, the relationship between the limit distance a′ and the inclination a in the linear approximation formula indicating the relationship between the size H of the gap h and the flow rate F is shown in FIG. 5. The linear approximation of the result shown in FIG. 5 gives a=0.1201*a′.

Therefore, as in the present embodiment, the position and the inclination of the discharge head with respect to the stage 11 are adjusted such that the size H of the gap h satisfies the following formula (A). Accordingly, the movement of radicals toward the central portion of the wafer W can be suppressed more reliably.

$$H \leq 0.12 * a * F \qquad ( A )$$

a: allowable distance
F: flow rate F of Ar gas discharged from the discharge head 15 (discharge hole 15b)

### Another Modification

FIG. 6 shows another example of the discharge head 15.

In the above example, the bottom surface 15a of discharge head 15 is flat.

However, as shown in FIG. 6, a bottom surface 15Aa of a discharge head 15A may have an upwardly recessed central portion. In this case, the peripheral portion of the bottom surface 15Aa of the discharge head 15A is located below the surface (front surface) of the wafer W placed on placing surface 11a, and is located above the backside of the wafer W. By using the discharge head 15A, even if the flow rate of the gas discharged from discharge head 15A is small, the movement of radicals toward the central portion of the wafer W can be suppressed. Accordingly, the consumption amount of the gas discharged from the discharge head 15A can be suppressed.

Further, when the discharge head 15A is used, the camera 60 detects the gap between the inner surface of the peripheral portion of the discharge head 15A and the edge surface of the wafer W placed on the placing surface 11a.

In the above example, the number of cameras 60 is the same as the number of detection points of the gap h. However, by using a reflection member or the like, the gap h may be detected by the cameras 60 (for example, one camera) of which number is less than the number of detection points of the gap h in each of the detection points of which number is greater than the number of cameras 60. This is also applied to the camera 62.

Further, in the above example, the gap h is detected by the camera 60 at multiple locations. However, the gap h may be detected at one location if the parallelism between the stage 11 and the discharge head (specifically, the parallelism between the wafer placed on the placing surface and the bottom surface of the discharge head) is ensured in advance.

In the above example, the discharge head 15 is smaller than the wafer W. However, the discharge head 15 may be greater than the wafer W. In this case, by providing another camera as the above-described another detection part at a position thereunder, the positional relationship between the peripheral edge of the discharge head 15 and the peripheral edge of the wafer W placed on the placing surface 11a can be detected. Specifically, the peripheral edge of the discharge head 15, which protrudes outward from the peripheral edge of the wafer W placed on the placing surface 11a when viewed from the bottom surface, can be detected.

In the above example, the camera as the detection part or the camera as another detection part is provided outside the processing chamber 10. Alternatively, at least one of the camera as the detection part and the camera as another detection part may be provided inside the processing chamber 10.

Further, in the above example, the detection part and another detection part are cameras. However, the detection parts are not limited thereto, and may be, for example, a distance measuring sensor.

In the above example, plasma (radicals) generated outside the processing chamber 10 is supplied into the processing chamber 10. However, an etching gas may be supplied into the processing chamber 10, and may be excited by the plasma generation device to generate plasma. The plasma thus generated may be supplied to the peripheral portion of the wafer W.

Further, in the above example, the adjustment mechanism for adjusting the relative position or inclination of the discharge head 15 and the stage 11 adjusts the position and inclination of the discharge head 15 with respect to the stage 11. However, instead of or in addition to the above, the position and inclination of the stage 11 with respect to the discharge head 15 may be adjusted.

In the above example, the discharge head 15 has one discharge hole 15b. However, the discharge head 15 may have a plurality of discharge holes 15b. When there are a plurality of discharge holes 15b, the discharge holes 15b may be formed near the peripheral portion of the wafer W.

In the above example, the discharge head 15 has an overall flat plate shape. However, the discharge head 15 may have an inverted mortar shape to form a large space at the central portion of the wafer W.

It should be noted that the above-described embodiments are illustrative in all respects and are not restrictive. The above-described embodiments may be omitted, replaced, or changed in various forms without departing from the scope of the appended claims and the gist thereof. For example, the components of the above-described embodiments can be randomly combined. The effects of the components for arbitrary combination can be obtained from the corresponding arbitrary combination, other effects apparent to those skilled in the art can also be obtained.

Further, the effects described in the present specification are merely explanatory or exemplary, and are not restrictive. In other words, in the technique related to the present disclosure, other effects apparent to those skilled in the art can be obtained from the description of the present specification in addition to the above-described effects or instead of the above-described effects.

The following configuration examples are also included in the technical scope of the present disclosure.
(1) A plasma processing apparatus for removing a film formed on a peripheral portion of a substrate by using plasma, comprising:
a processing chamber configured to be depressurized and accommodate a substrate;
a substrate support provided in the processing chamber and having an upper surface serving as a placing table on which a substrate is placed;
a discharge head provided above the substrate support and configured to discharge a gas toward the placing surface;
a plasma supply mechanism configured to supply plasma to an edge of the substrate placed on the placing surface; and
an adjustment mechanism configured to adjust a relative position and inclination of the discharge head and the substrate support.
(2) The plasma processing apparatus of (1), further comprising:
a detection part configured to detect a gap between a bottom surface of a peripheral portion of the discharge head and a surface of the substrate placed on the placing surface.
(3) The plasma processing apparatus of (2), further comprising:
another detection part configured to detect a positional relationship between a peripheral edge of the discharge head and a peripheral edge of the substrate placed on the placing surface.
(4) The plasma processing apparatus of (2), further comprising:
a controller,
wherein the controller is configured to control the adjustment mechanism based on a detection result of the detection part to adjust at least one of the relative position and the inclination of the discharge head and the substrate support.
(5) The plasma processing apparatus of (3), further comprising:
a controller,
wherein the controller is configured to control the adjustment mechanism based on a detection result of the detection part and said another detection part to adjust at least one of the relative position and the inclination of the discharge head and the substrate support.
(6) The plasma processing apparatus of any one of (2) to (5), wherein the detection part is provided to detect the gap in at least three locations along a circumferential direction of the placing surface.
(7) The plasma processing apparatus of (3) or (5), wherein said another detection part is a camera.
(8) The plasma processing apparatus of any one of (2) to (7), wherein the detection part is a camera.
(9) The plasma processing apparatus of any one of (1) to (8), wherein a flow rate of the gas discharged from the discharge head is a flow rate at which the Peclet number between the discharge head and the placing surface is 1 to 100.
(10) The plasma processing apparatus of any one of (1) to (9), wherein when a flow rate of the gas discharged from the discharge head is set to F, and
a distance from a peripheral edge of the discharge head that allows radicals, as the plasma, to reach a central portion of the substrate through a gap between a bottom surface of a peripheral portion of the discharge head and a surface of the substrate placed on the placing surface is set to a,
the adjustment mechanism is configured to adjust a size H of the gap to satisfy a following formula (A).

$$H \leq 0.12 * a * F \qquad ( A )$$

(11) A plasma processing method for removing a film formed on a peripheral portion of a substrate by plasma using a plasma processing apparatus,
wherein the plasma processing apparatus includes:
a processing chamber configured to be depressurized and accommodate a substrate;
a substrate support provided in the processing chamber and having an upper surface serving as a placing surface on which a substrate is placed;
a discharge head provided above the substrate support and configured to discharge a gas toward the placing surface; and
an adjustment mechanism configured to adjust a relative position and inclination of the discharge head and the substrate support,
the plasma processing method comprising:
placing a substrate on the placing surface;
detecting a gap between a bottom surface of a peripheral portion of the discharge head and a surface of the substrate placed on the placing surface; and
adjusting a size of the gap by adjusting any one of the relative position and inclination of the discharge head and the substrate support based on a gap detection result.

1. A plasma processing apparatus for removing a film formed on a peripheral portion of a substrate by using plasma, comprising:
a processing chamber configured to be depressurized and accommodate a substrate;
a substrate support provided in the processing chamber and having an upper surface serving as a placing table on which a substrate is placed;
a discharge head provided above the substrate support and configured to discharge a gas toward the placing surface;
a plasma supply mechanism configured to supply plasma to an edge of the substrate placed on the placing surface; and
an adjustment mechanism configured to adjust a relative position and inclination of the discharge head and the substrate support.

2. The plasma processing apparatus of claim 1, further comprising:
a detection part configured to detect a gap between a bottom surface of a peripheral portion of the discharge head and a surface of the substrate placed on the placing surface.

3. The plasma processing apparatus of claim 2, further comprising:
another detection part configured to detect a positional relationship between a peripheral edge of the discharge head and a peripheral edge of the substrate placed on the placing surface.

4. The plasma processing apparatus of claim 2, further comprising:
a controller,
wherein the controller is configured to control the adjustment mechanism based on a detection result of the detection part to adjust at least one of the relative position and the inclination of the discharge head and the substrate support.

5. The plasma processing apparatus of claim 3, further comprising:
a controller,
wherein the controller is configured to control the adjustment mechanism based on a detection result of the detection part and said another detection part to adjust at least one of the relative position and the inclination of the discharge head and the substrate support.

6. The plasma processing apparatus of claim 2, wherein the detection part is provided to detect the gap in at least three locations along a circumferential direction of the placing surface.

7. The plasma processing apparatus of claim 3, wherein said another detection part is a camera.

8. The plasma processing apparatus of claim 2, wherein the detection part is a camera.

9. The plasma processing apparatus of claim 1, wherein a flow rate of the gas discharged from the discharge head is a flow rate at which the Peclet number between the discharge head and the placing surface is 1 to 100.

10. The plasma processing apparatus of claim 1, wherein when a flow rate of the gas discharged from the discharge head is set to F, and
a distance from a peripheral edge of the discharge head that allows radicals, as the plasma, to reach a central portion of the substrate through a gap between a bottom surface of a peripheral portion of the discharge head and a surface of the substrate placed on the placing surface is set to a,
the adjustment mechanism is configured to adjust a size H of the gap to satisfy a following formula (A)
$$H \leq 0.12 * a * F . \qquad ( A )$$

11. A plasma processing method for removing a film formed on a peripheral portion of a substrate by plasma using a plasma processing apparatus,
wherein the plasma processing apparatus includes:
a processing chamber configured to be depressurized and accommodate a substrate;
a substrate support provided in the processing chamber and having an upper surface serving as a placing surface on which a substrate is placed;
a discharge head provided above the substrate support and configured to discharge a gas toward the placing surface; and
an adjustment mechanism configured to adjust a relative position and inclination of the discharge head and the substrate support,
the plasma processing method comprising:
placing a substrate on the placing surface;
detecting a gap between a bottom surface of a peripheral portion of the discharge head and a surface of the substrate placed on the placing surface; and
adjusting a size of the gap by adjusting any one of the relative position and inclination of the discharge head and the substrate support based on a gap detection result.
